(19) United States
(12) Patent Application Publication
(10) Pub. No.: US 2025/0076833 A1
(43) Pub. Date: Mar. 6, 2025

(54) POWER CONSUMPTION MEASUREMENT OF POOL OR SPA EQUIPMENT USING A POOL AUTOMATION CONTROLLER

(71) Applicant: ZODIAC POOL SYSTEMS LLC, Carlsbad, CA (US)

(72) Inventors: Minas Minassian, Carlsbad, CA (US); Darin Eames, Carlsbad, CA (US); Mark J. Bauckman, San Marcos, CA (US)

(73) Assignee: ZODIAC POOL SYSTEMS LLC, Carlsbad, CA (US)

(21) Appl. No.: 18/821,974

(22) Filed: Aug. 30, 2024

Related U.S. Application Data
(60) Provisional application No. 63/579,587, filed on Aug. 30, 2023.

(51) Int. Cl. G05B 19/042

(52) U.S. Cl. CPC G05B 19/042; G05B 2219/2639

(57) ABSTRACT

Systems and methods for power consumption measurement of pool or spa equipment using a pool automation controller are provided. An example pool automation controller includes inductance coils configured to measure a current induced by an alternating-current (“AC”) electrical input, control devices configured to control power directed to one or more pieces of pool or spa equipment electrically connected to the AC electrical input, and a computing device. The computing device instructs one or more processors to perform operations including identifying a piece of pool or spa equipment based on a status of a control device. The operations further include receiving information about one or more induced currents from the inductance coils. The operations further include determining a power consumption by the piece of pool or spa equipment based on the one or more induced currents. The operations further include outputting the power consumption.

### CROSS-REFERENCE TO RELATED APPLICATION

This application claims priority to provisional application U.S. Ser. No. 63/579,587 entitled “Load Power Sensing With Pool Automation Controller” and filed on Aug. 30, 2023, the entire disclosure of which is incorporated herein by reference for any purpose.

### FIELD

The present disclosure relates generally to pool automation systems and more particularly, although not exclusively, to power consumption measurement of pool or spa equipment using a pool automation controller.

### BACKGROUND

Pool and spa systems may include a variety of equipment, such as pumps, vacuum ports, lights, heaters, cleaners, filters, etc. Equipment may be controlled by a pool automation controller by various means, such as relays or digital signals. However, equipment may lack the capability to report to the pool automation controller their power consumption. As a result, the pool automation controller may only be able to report and respond to the power consumption of the entire pool system.

### SUMMARY

In one general aspect, a pool automation controller may include one or more inductance coils configured to measure a current induced by an alternating-current (“AC”) electrical input. The pool automation controller may also include one or more control devices configured to control power directed to one or more pieces of pool or spa equipment electrically connected to the AC electrical input. The controller may furthermore include one or more non-transitory computer-readable media; and one or more processors communicatively coupled to the one or more non-transitory computer-readable media, the one or more processors configured to execute processor-executable instructions stored in the non-transitory computer-readable media to perform operations including: identifying a first piece of pool or spa equipment based on a status of a first control device; receiving information about one or more first induced currents from the one or more inductance coils; determining a first power consumption by the first piece of pool or spa equipment based on the one or more first induced currents; and outputting the first power consumption.

Implementations may include one or more of the following features. In some examples, the one or more control devices include an electromechanical relay for operating a remote switch.

In some examples, the one or more control devices include a digital controller for operating a remote switch.

In some examples, the AC electrical input is a split-phase AC electrical input having two hot wires and a neutral wire; and each of the two hot wires has a corresponding inductance coil.

In some examples, the pool automation controller may in addition include a processing subsystem, the processing subsystem having: an amplifier for each of the one or more inductance coils; and a digitizer, where the information about the one or more first induced currents may include a measurement of the current in each phase of the split-phase AC electrical input.

In some examples, the AC electrical input is a single-phase AC electrical input having a hot wire and a neutral wire; and the hot wire has a corresponding inductance coil.

In some examples, a plurality of pieces of pool or spa equipment are electrically connected to the AC electrical input, and determining the first power consumption by the first piece of pool or spa equipment based on the one or more first induced current may include: outputting a first command to the one or more control devices to cause all of the plurality of pieces of pool or spa equipment other than the first piece of pool or spa equipment to be unpowered by the electrical input; measuring the one or more first induced currents; and computing the first power consumption of the first piece of pool or spa equipment using the one or more first induced currents.

In some examples, the operations may include: outputting a second command to the one or more control devices to cause the first piece of pool or spa equipment to be unpowered by the electrical input; outputting a third command to the one or more control devices to cause a second piece of pool or spa equipment to be powered by the electrical input; outputting a fourth command to the one or more control devices to cause all other pieces of pool or spa equipment other than the second piece of pool or spa equipment to be unpowered by the electrical input; and determining a second power consumption of the second piece of pool or spa equipment based on one or more second induced currents.

In some examples, a plurality of pieces of pool or spa equipment are electrically connected to the AC electrical input, and determining the first power consumption by the first piece of pool or spa equipment based on the one or more first induced current may include: outputting a first command to the one or more control devices to cause all of the plurality of pieces of pool or spa equipment to be powered by the AC electrical input; measuring one or more second induced currents; outputting a second command to the one or more control devices to cause the first piece of pool or spa equipment to be unpowered by the AC electrical input; measuring the one or more first induced currents; and computing the first power consumption of the first piece of pool or spa equipment using a difference between the one or more second induced currents and the one or more first induced currents.

In some examples, the operations may include: configuring the first piece of pool or spa equipment to operate in a first mode of operation; determining a second power consumption based on one or more second induced currents while the first piece of pool or spa equipment is operating in the first mode of operation; configuring the first piece of pool or spa equipment to operate in a second mode of operation; determining a third power consumption based on one or more third induced currents while the first piece of pool or spa equipment is operating in the second mode of operation; and determining a power consumption profile of the first mode of operation based on a difference between the second power consumption and the third power consumption.

In some examples, the first piece of pool or spa equipment is a heater, a light, a cleaner, or a circulation pump.

In some examples, a plurality of pieces of pool or spa equipment are electrically connected to the AC electrical input, and the operations may further include: determining a power consumption measurement plan having instructions, each instruction including at least one command to the one or more control devices to power or remove power from a particular piece of pool or spa equipment of the plurality of pieces of pool or spa equipment from the AC electrical input to enable a power consumption measurement; and executing the power consumption measurement plan to cause a power consumption measurement for each of the plurality of pieces of pool or spa equipment.

In some examples, the operations may include combining the power consumption measurement for each of the plurality of pieces of pool or spa equipment to compute an aggregate power consumption measurement.

In some examples, the operations may include, responsive to the first power consumption exceeding a predetermined threshold, outputting a command to the one or more control devices to cause the first piece of pool or spa equipment to be unpowered by the AC electrical input.

In another general aspect, a method may include receiving information about one or more first induced currents from one or more inductance coils configured to measure a current induced by an AC electrical input. The method may also include identifying a first connected piece of pool or spa equipment based on a status of a first control device configured to control power to an electrically connected piece of pool or spa equipment of a plurality of pieces of pool or spa equipment from the AC electrical input. The method may furthermore include determining a first power consumption by the first connected piece of pool or spa equipment based on the one or more first induced currents and outputting the first power consumption.

Implementations may include one or more of the following features. In some examples, determining the first power consumption by the first connected piece of pool or spa equipment based on the one or more first induced current may include: outputting a first command to one or more control devices, including the first control device, to cause all pieces of pool or spa equipment other than the first connected piece of pool or spa equipment to be unpowered by the AC electrical input; and measuring the one or more first induced currents, the method may include: outputting a second command to the one or more control devices to cause the first connected piece of pool or spa equipment to be unpowered by the AC electrical input; outputting a third command to the one or more control devices to cause a second connected piece of pool or spa equipment to be powered by the AC electrical input; and determining a second power consumption of the second connected piece of pool or spa equipment based on one or more second induced currents.

In some examples, determining the first power consumption by the first connected piece of pool or spa equipment based on the one or more first induced current may include: outputting a first command to one or more control devices, including the first control device, to cause all of the plurality of pieces of pool or spa equipment to be powered by the AC electrical input; measuring one or more second induced currents; outputting a second command to the one or more control devices to cause the first connected piece of pool or spa equipment to be unpowered by the AC electrical input; measuring the one or more first induced currents; and computing the first power consumption of the first connected piece of pool or spa equipment using a difference between the one or more second induced currents and the one or more first induced currents.

In some examples, the method may further include: configuring the first connected piece of pool or spa equipment to operate in a first mode of operation; determining a second power consumption based on one or more second induced currents while the first connected piece of pool or spa equipment is operating in the first mode of operation; configuring the first connected piece of pool or spa equipment to operate in a second mode of operation; determining a third power consumption based on one or more third induced currents while the first connected piece of pool or spa equipment is operating in the second mode of operation; and determining a power consumption profile of the first mode of operation based on a difference between the second power consumption and the third power consumption.

In some examples, the method may in addition include: determining a power consumption measurement plan having instructions, each instruction including at least one command to one or more control devices, including the first control device, to power or remove power from a particular piece of pool or spa equipment of the plurality of pieces of pool or spa equipment from the AC electrical input to enable a power consumption measurement; executing the power consumption measurement plan to cause a power consumption measurement for each of the plurality of pieces of pool or spa equipment; and combining the power consumption measurement for each of the plurality of pieces of pool or spa equipment to compute an aggregate power consumption measurement.

In another general aspect, a non-transitory computer-readable medium storing processor-executable instructions may receive information about one or more induced currents from one or more inductance coils configured to measure a current induced by an AC electrical input. The instructions may include identifying a first connected piece of pool or spa equipment based on a status of a first control device configured to control power to an electrically connected piece of pool or spa equipment of a plurality of pieces of pool or spa equipment from the AC electrical input. The instructions may furthermore include determining a power consumption by the first connected piece of pool or spa equipment based on one or more first induced currents and outputting the power consumption.

### BRIEF DESCRIPTION OF THE DRAWINGS

The accompanying drawings, which are incorporated into and constitute a part of this specification, illustrate one or more certain examples and, together with the description of the example, serve to explain the principles and implementations of the certain examples.

FIG. 1 illustrates an example pool or spa system controlled by a pool automation controller, according to some examples of the present disclosure.

FIG. 2 illustrates an example flow diagram showing a process for power consumption measurement of pool or spa equipment using a pool automation controller, according to some examples of the present disclosure.

FIG. 3 shows a flow chart depicting an example process for iteratively testing the power consumption of equipment in a pool or spa system, according to some examples of the present disclosure.

FIG. 4 shows another flow chart depicting an example process for iteratively testing the power consumption of equipment in a pool or spa system, according to some examples of the present disclosure.

FIG. 5 shows a flow chart depicting an example process for iteratively deducing the power consumption of equipment in a pool or spa system, according to some examples of the present disclosure.

FIG. 6 illustrates examples of a computer system that can be used for power consumption measurement of pool or spa equipment using a pool automation controller, according to some examples of the present disclosure.

### DETAILED DESCRIPTION

Examples described herein relate to systems, devices, and techniques for power consumption measurement of pool or spa equipment using a pool automation controller. Those of ordinary skill in the art will realize that the following description is illustrative only and is not intended to be in any way limiting. Reference will now be made in detail to implementations of examples as illustrated in the accompanying drawings. The same reference indicators will be used throughout the drawings and the following description to refer to the same or like items.

In the interest of clarity, not all of the routine features of the examples described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another.

Centralized control of pool and spa equipment using a pool automation controller is convenient and efficient. Moreover, such a configuration can be combined with modern computer processing methods to further improve on conventional or manual methods for operating and maintaining pools, spas, and the associated connected equipment. For example, computer processing methods can be used for automated water quality management, scheduled or planned equipment operations, integration with smart home systems, and so on.

Such applications are enabled by controlling power to pool or spa equipment with the pool automation controller using control devices such as relays or digital signals through, e.g., RS-485 serial control. Despite this, existing systems may lack the capability to determine and report power consumption at a granular level without significant compromises to usability or accuracy. For example, existing systems cannot determine the power consumption of a single piece of pool or spa equipment or the power consumption of a particular mode of operation of a piece of pool or space equipment. As a result, the pool automation controller may only be able to report and respond to the power consumption of the entire pool or spa system. As used herein, “power consumption” refers generally to the rate at which electrical energy is used or consumed by pool or spa equipment, typically measured in watts or kilowatts.

Realtime measurement of power consumption of individual devices can allow for precision management of energy usage, leading to cost savings and enhanced operational efficiency as well as the identification of specific equipment inefficiencies or malfunctions. Additionally, measurement of power consumption may be used for reducing the environmental impact of the use of pool and spa equipment.

For example, existing approaches for measuring the power consumption of individual pieces of pool or spa equipment may involve receiving information about equipment current draw using pickup coils locally installed near each piece of equipment. For instance, a pool automation controller installed in a pool shed may be connected by long wires to a locally installed pickup coil near each piece of equipment. However, installing pickup coils near each piece of equipment requires extensive wiring and setup that can be both labor-intensive and expensive, leading to higher installation costs and increased potential for wiring errors or failures. Moreover, locally installed pickup coils can result in maintenance challenges due to difficulties accessing the coils for inspection, troubleshooting, or replacement.

In some existing approaches, techniques based on machine learning (“ML”) can be used to train and use models that can predict power consumption of individual pieces of equipment based on various electrical inputs. However, the accuracy of such ML models depends heavily on training and may not always generalize. Moreover, the development and maintenance of ML models necessitates ongoing monitoring. ML models may also lack the precision that is needed for management of complex pool and spa systems.

These challenges can be addressed using the systems, devices, and techniques for power consumption measurement of pool or spa equipment using a pool automation controller disclosed herein. In an illustrative example, consider an example pool automation controller used in conjunction with a particular pool. A number of pieces of equipment are used during operation and maintenance of the pool such as a heater, a light, a cleaner, and a circulation pump, among others. The pool automation controller can be used to control the equipment using control devices that direct power to the equipment such as remotely operated relays, digital controls, or other types of remote control devices to activate, deactivate, or change the mode of the equipment. The pool automation controller can be used to measure the power consumption of the equipment. In this example, the pool automation controller includes a pair of inductance coils configured to measure a current induced by an AC electrical input to the pool automation controller. For example, the electrical input may be a connection to a residential electrical supply configured for high-voltage applications.

The example pool automation controller further includes a computing device that can identify a piece of pool equipment based on the status of one of the control devices. For example, the computing device may be used to issue commands to a control device to direct power to a circulation pump from the electrical input. The computing device then receives information about induced currents from the inductance coils. For example, the induced analog current signal can be digitized using analog-to-digital converters (“ADCs”) that can be amplified and received as inputs to the computing device. The information about the induced currents is then used to determine the power consumption of the pump. For example, the computing device can determine a difference between the induced current measured before and after the connection of the pump to the electrical input, along with other information such as the characteristics of the inductance coils and the voltage supplied by the electrical input, to compute the power consumed by the pump. The measured power consumption of the pump is then output using a suitable display or graphical user interface (“GUI”) and may be incorporated into other applications such as determination of a sustainability score or an aggregate power consumption measurement.

In another example, the pool automation controller may be used to selectively measure power consumption of individual pieces of pool equipment according to a power consumption measurement plan. For example, the pool automation controller may issue commands to a control device, such as a digital controller, to instruct all equipment through a serial controller, except the circulation pump, to power down such that the circulation pump is the only equipment drawing power. The pool automation controller may then use the computing device to measure the induced currents in the coils during a fixed time interval. After recording a measurement for the power consumption of the circulation pump, the pool automation controller may issue additional commands via the digital controller to power down the circulation pump and then to power on a water heater using another control device, such as a remotely operated electromechanical relay. The process can then be repeated to derive the power consumption of the water heater. Additionally, the pool automation controller can be configured to also measure power consumption at a different level of granularity than just on and off. For example, when isolating a pump to measure power, the pump may be operated at different modes for more precise characterization such as at different speeds. Additional signals about system status may also be considered. For example, valve positions or other valve settings may contribute various back pressure effects to the system. Information about the valve positions and other valve settings can be used to adjust the computed power consumption for different modes to correct for such effects. In this manner, the pool automation controller can determine not only how different modes/states of a piece of equipment might impact power consumption (e.g., adjusting speeds of a pump), but also how other items in the system that are separate from the piece of equipment might impact power consumption of the piece of equipment (e.g., how a valve setting in the system may impact power consumption of a pump at each of a variety of speeds).

In addition to the advantages described above, measuring the power consumption of pool or spa equipment by measuring current flow at the pool automation controller may obviate the need to install additional electronics that would otherwise be needed to measure the power consumption of individual equipment. Many items of pool or spa equipment are not equipped with electronics capable of recording or reporting the component's power consumption. This may be particularly true of legacy equipment that lacks modern electronics or microprocessors. Installing additional electronics on these pool or spa equipment may be expensive and impractical, especially if the items of equipment are underground. While the pool automation controller may be able to measure the power consumption of equipment without receiving a signal directly from the equipment, the pool automation controller may also be able to receive reports of power consumption from equipment that are capable of reporting power consumption. In such an example, the pool automation controller may make recommendations that consider both power consumption information derived from the energy measurement circuit of the pool automation controller as well as data from pool or spa equipment.

These illustrative examples are given to introduce the reader to the general subject matter discussed herein and the disclosure is not limited to these examples. The following sections describe various additional non-limiting examples of systems and methods for power consumption measurement of pool or spa equipment using a pool automation controller.

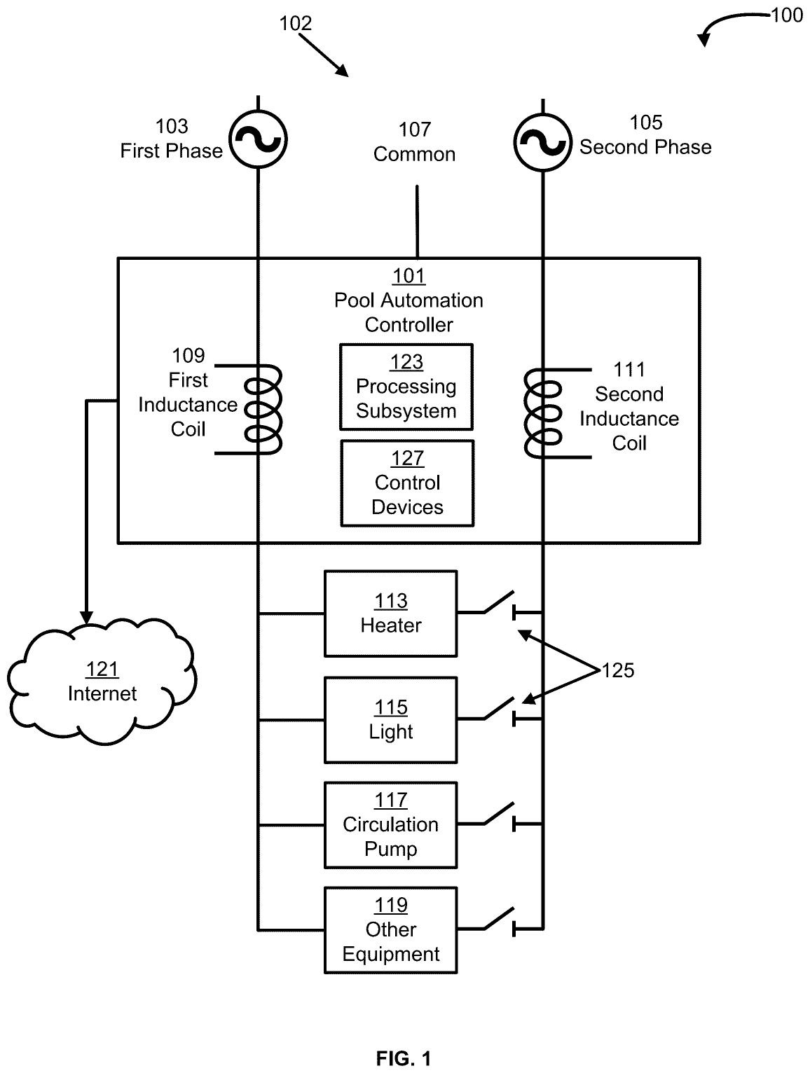

Turning now to the figures, FIG. 1 illustrates an example pool or spa system 100 controlled by a pool automation controller 101, according to some examples of the present disclosure. The pool automation controller 101 includes a first inductance coil 109 for reading a first phase 103 of current and a second inductance coil 111 for reading a second phase 105 of current. The first and second coils 109 and 111 can be configured to measure the magnitude of AC electrical input 102 provided by the first phase 103, the second phase 105, and common line 107. In various configurations, the common line 107 may be referred to variously as the common, neutral, or ground line or wire.

The first inductance coil 109, second inductance coil 111, and other inductance coils may be disposed within the pool automation controller 101. For example, the pool automation controller 101 may include an external housing that contains the inductance coils 109, 111, processing subsystem 123, and a connection to the electrical input 102. The inductance coils 109, 111 may be any suitable inductance coil for measurement of the induced current associated with changing pool or spa equipment currents. Parameters such as coil inductance, current rating, frequency range, sensitivity, physical dimensions, and so on, may be selected in accordance with the particular application such as the expected electrical loading and current ranges (e.g., magnitude or time rate of change).

For some pool or spa systems, the electrical input 102 may be a residential or commercial AC electrical input. The electrical input 102 may be connected to the pool automation controller 101 such that the inductance coils 109 and 111 are contained within the pool automation controller 101. The electrical input 102 may be a split-phase AC electrical input including two hot wires (103 and 105) and a common (or neutral) wire (107), as shown in the example system 100. In that case, each of the two hot wires has a corresponding inductance coil, 109 and 111. In some other example systems, the electrical input 102 may be a single-phase AC electrical input including a single hot wire and a neutral wire, where the hot wire has a corresponding single inductance coil. Other electrical configurations involving AC electrical power can be used with the techniques describes herein including three-phase AC electrical input, variable frequency AC electrical input, and various AC configurations as may be implemented internationally.

The alternating-current for each of the first phase 103 and the second phase 105 pass through the respective coils 109 and 111 within the pool automation controller 101 causing an induced current in the coils 109 and 111. The induced current from the coils 109 and 111 can by digitized by the pool automation controller 101 and measured to compute the power consumption of the connected pieces of pool or spa equipment. For example, the coils 109 and 111 each can be connected to an amplifier and a digitizer (not shown). The digitizer can be used to make measurements of the current in each phase of the split-phase AC electrical input or other electrical configuration.

As mentioned above, power consumption refers to the rate at which electrical energy is used or consumed by pool or spa equipment, sometimes measured in kilowatts or kilowatt-hours. Power consumption is a useful measure of electrical energy usage that may be used by utility providers or regulators for billing, computing tax rebates, and so forth. However, other measures of electrical energy usage that can be measured using induction may be likewise used with the techniques described herein.

The example system 100 depicts pool automation controller 101 supplying power to pool or spa equipment including a heater 113, a light 115, a circulation pump 117, and other equipment 119 of the pool system 100. These components are merely non-limiting examples and any suitable electrical device used for pool or spa operation, maintenance, monitoring, or other purpose may be similarly compatible with the system 100.

The pool or spa equipment is schematically shown connected in parallel to the hot wires (103, 105) of electrical input 102 using switches 125. The switches 125 may be remotely operable mechanical actuators, electromechanical switches (e.g., solenoid controls), or other electrical or digital controls. For example, the switches 125 may include digital controls operated through an RS-485 serial communication link or other electronic or microprocessor-based control signals. In addition to the parallel connections depicted, the equipment may be connected in series or using more complex variations on series and parallel connections.

The pool automation controller 101 may include processing subsystem 123 for calculating power consumption based on induced currents read from the first coil 109 and the second coil 111 as well as other processing functions implemented using instructions. In some examples, the pool automation controller 101 may be connected to a standalone processing subsystem 123. The processing subsystem 123 may be a standalone circuit or may be implemented within the pool automation controller. In some examples, the processing subsystem 123 may be a hardware or software component of a computing system such as an embedded computer, mobile device, or a combination of such components. Likewise, some components of the system 100 may be hosted in a cloud-computing environment accessible over the internet 121, as described below. The processing subsystem 123 can be configured to executed program code in a memory using suitable software, hardware, firmware, or any combination thereof.

The switches 125 are controlled by processing subsystem 123 using control devices 127 configured to control power to the pool or spa equipment. “Controlling power” can refer generally to various operations that change the power consumption of the equipment. For instance, controlling power can include turning equipment on or off (e.g., operating a power switch or button), connecting or disconnecting the equipment, operating a switch that closes or opens an energized circuit, or changes a mode of operation (e.g., throttling power, changing speeds, varying modes, etc.). The control devices 127 may include relays such as electromechanical relays, solid-state relays, and the like. The relays can be used to actuate remotely controlled mechanical actuators, electromechanical switches, and so on. The control devices 127 may also include a digital controller that controls power directed to the pool or spa equipment through a an RS-485 serial controller, Ethernet controller, microprocessor controller, etc. In some examples, the switches 125 may be located inside the pool automation controller 101 housing, in which case some switches 125 and control devices 127 may be combined. For example, local electromechanically actuated relay may also function as a switch.

The pool automation controller 101 is also connected to the internet 121, which may enable connectivity to a server with information related to power utility rates, peak energy rate usage, specified power consumption of replacement pool equipment, algorithms for optimizing power consumption, algorithms for optimizing performance, and other information related to power consumption of the pool system 100.

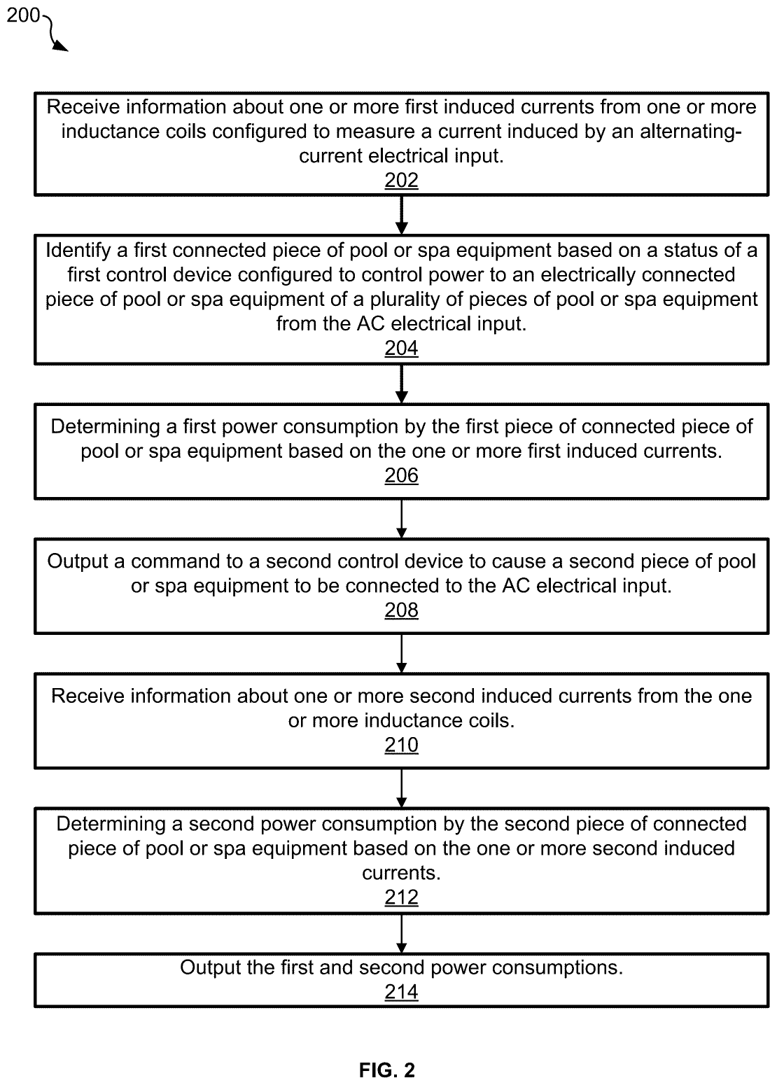

FIG. 2 illustrates an example flow diagram showing a process 200 for power consumption measurement of pool or spa equipment using a pool automation controller, according to some examples of the present disclosure. This process, and any other processes described herein, is illustrated as a logical flow diagram, each operation of which represents a sequence of operations that can be implemented in hardware, computer instructions, or a combination thereof. In the context of computer instructions, the operations may represent computer-executable instructions stored on one or more non-transitory computer-readable storage media that, when executed by one more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the process.

Additionally, some, any, or all of the processes described herein may be performed under the control of one or more computer systems configured with specific executable instructions and may be implemented as code (e.g., executable instructions, one or more computer programs, or one or more applications) executing collectively on one or more processors, by hardware, or combinations thereof. As noted above, the code may be stored on a non-transitory computer-readable storage medium, for example, in the form of a computer program including a plurality of instructions executable by one or more processors.

At block 202, a computing system, such as the processing subsystem 123 shown in example system 100 of FIG. 1, receives information about one or more first induced currents from one or more inductance coils configured to measure a current induced by an AC electrical input. For example, the system 100 includes two inductance coils 109 and 111, but other configurations involving one, three, or other numbers of inductance coils can be used in the context of process 200.

The information about the induced currents may be received by way of an analog-to-digital conversion (“ADC”) in which the analog induced currents are converted into digital signals using a sampling process that quantizes the continuous analog signal into discrete digital values. This digital data can then be processed by the processing subsystem 123 to perform various power consumption measurements as described below to enable precision control and monitoring of the system 100.

At block 204, the computing system identifies a first connected piece of pool or spa equipment based on a status of a first control device configured to control power to an electrically connected piece of pool or spa equipment of a plurality of pieces of pool or spa equipment from the AC electrical input. For example, the first piece of equipment may be a heater that is connected to the two phases of an AC electrical input. The heater may be connected by way of a remotely operated relay, such as a solid-state relay or an electromechanical relay, which allows the heater to be powered on or off remotely by, for example, the processing subsystem 123 using a control device 127. Controlling power to the electrically connected piece of equipment can include turning power on or off (e.g., operating a power switch or button), connecting/disconnecting a mechanical switch, operating an electronic switch to start or stop current in a circuit, changing the mode of a piece of equipment using a relay or digital control, and so on. The status of the remotely operable relay can be ascertained using an electrical relay (e.g., an energized solenoid), a digital signal, and so on. In some examples, the status of the remotely operable relay may be based on the associated status of the control device 127. For example, the status of the relay may be based on the corresponding status of a digital controller that controls the relay.

At block 206, the computing system determines a first power consumption by the first piece of connected piece of pool or spa equipment based on the one or more first induced currents. In some examples, the first power consumption can be computed using a difference in the measured induced current. For instance, the processing subsystem 123 can derive the power consumption of the first pool equipment by powering down the first pool equipment and monitoring the resulting change in induced current. In another example, the processing subsystem 123 can derive the power consumption of the first pool equipment by powering down all other pool equipment and measuring the remaining induced current.

In some examples, measuring the power consumption of equipment of a pool or spa system may be performed according to a switching algorithm executed by the processing subsystem 123. A “switching algorithm” may refer generally to a series of instructions for making power consumption measurements. The processing subsystem 123 may measure the power consumption of equipment by taking current measurements with the first coil 109 and second coil 111 of the pool automation controller 101 and derive power consumption from the current measurements. The processing subsystem 123 may take such measurements by recording changes in the first phase 103 and second phase 105 of an alternating current used to power the pool or spa system. Such changes may occur as equipment is switched on and off using the control devices 127 according to the algorithm executed by the processing subsystem 123.

For instance, an example algorithm for measuring the power consumption of pool equipment may involve powering down all equipment, then powering on individual items of equipment one at a time to record the changes in current through the coils. Alternatively, an example algorithm may involve powering on all equipment, then powering down individual equipment one at a time to record the changes in current through the coils. Other algorithms or processes for deducing the power consumption of individual pieces of equipment are also possible. The pool automation controller 101 may control power to some equipment by actuating a relay to operate a remote switch (e.g., a solenoid control or electromechanical actuator) and some equipment by digital signal. In the latter case, a piece of pool or spa equipment may include local electronic or microprocessor control that can be remotely signaled using a digital control interface through an RS-485 serial controller or the like.

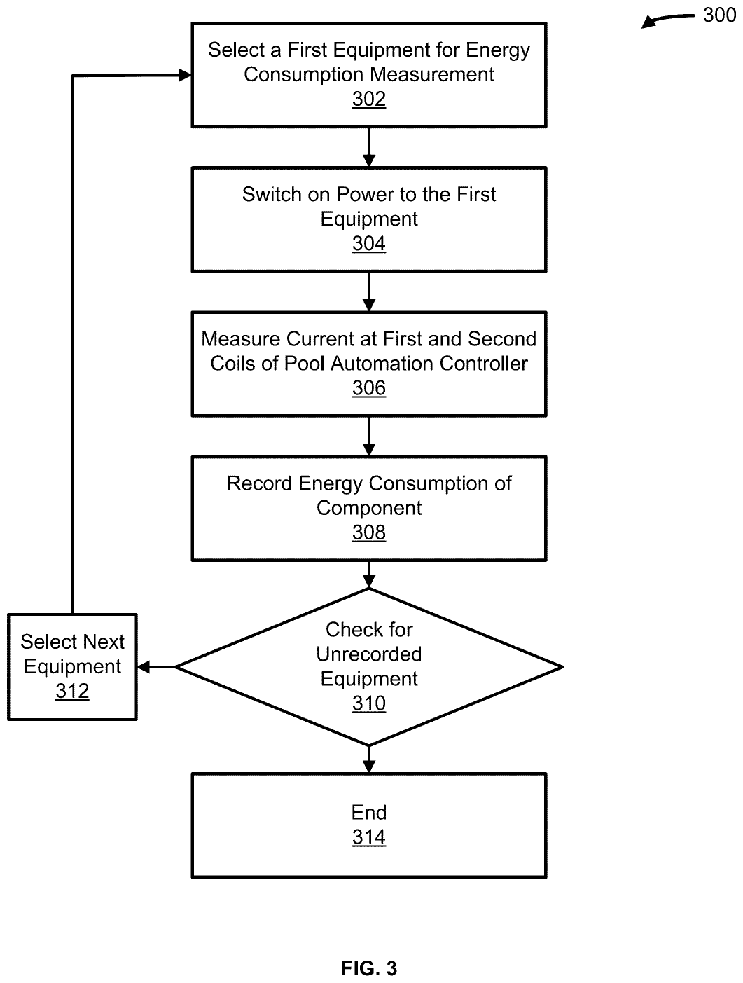

For example, the processing subsystem 123 can be configured to determine a power consumption measurement plan. The power consumption measurement plan can include instructions to effectuate a particular relay or other control device 127 to control power to a particular piece of pool or spa equipment of the plurality of pieces of pool or spa equipment using a remotely operated switch or digital control from the electrical input to enable a power consumption measurement. Execution of the power consumption measurement plan can be used to cause a power consumption measurement for each of the plurality of pieces of pool or spa equipment. Examples of such algorithms are described in detail in FIGS. 3, 4, and 5 below.

Switching algorithms can likewise be used for various aggregate or derivative calculations. For instance, the measurements of the power consumption measurement plan can be combined to compute an aggregate power consumption measurement that indicates the power consumption of all or a subset of all of the pieces of pool or spa equipment.

In some examples, the process 200 can be used for calculating an energy sustainability score or a performance score based on measurements from the pool automation controller 101. In some examples, calculating the sustainability score or the performance score may be calculated by the processing subsystem 123. In some examples, the pool automation controller 101 may send measurements over the internet 121 for a remote server to calculate the scores. For instance, the current measurements may be made within the pool automation controller 101 but exported as raw data for processing and analysis.

The sustainability score may be reflective of a pool or spa system operating at specific parameters, such as heater temperature settings, circulation pump revolutions per minute (“RPM”) settings, water consumption, natural gas consumption, etc. The sustainability score may consist of multiple metrics, such as estimated operating cost, electrical power consumption in kilowatt hours, natural gas consumption in cubic feet, estimated carbon dioxide emissions in cubic feet, equipment wear, and/or other metrics as desired. The performance score may also be reflective of a pool or spa system operating at specific parameters, such as the aforementioned examples. The performance score may consist of multiple metrics, such as an estimated time to heat the pool to the preset thermostat setting, an estimated time to fill the pool, etc. Either score may be determined with the measurements taken by the pool automation controller 101 and optionally with information available from the internet 121, such as peak energy rate usages, etc. Either score may also be determined with signals from the alternating current, such as demand-response signals.

In another example of an aggregate or derivative operation, the process 200 can provide feedback, such as but not limited to a suggested schedule, operating parameters, product suggestions, and/or other suggestions predicted by the pool automation controller 101 to improve the sustainability or performance score of the pool system 100. Provided suggestions may include how the performance score and/or sustainability score may be altered. The processing subsystem 123 of the pool automation controller 101 or a server connected to the pool automation controller 101 by an internet 121 connection may determine how the suggestions impact the scores. The feedback may be reported to the pool automation controller 101. For example, a suggested schedule reported to the pool automation controller 101 may inform a user that running the pool heater 113 from 3:00 P.M. to 5:00 P.M. rather than the peak usage hours of 6:00 P.M. to 8:00 P.M. may save the user an estimated 13 dollars, where the estimated savings are part of the sustainability score. An example product suggestion may inform the user that purchasing additional pumps may reduce the time to fill the pool by 4 hours, where the estimated time to fill the pool is part of a performance score. Example suggested operating parameters may inform the user that adjusting the RPMs of a circulation pump 117 may increase the life of the pump 117 by 70 operating hours, where the hours of operable use are part of the sustainability score.

The estimated impact of the feedback (e.g., suggested schedule, operating parameters, or product suggestions, etc.) may be calculated by either the processing subsystem 123 of the pool automation controller 101 or from a server connected to the pool automation controller 101 by the internet 121. The server or the processing subsystem 123 of the pool automation controller 101 may draw from information available on the internet, such as product information, weather forecasts, or peak energy usage rages, to determine the appropriate suggestions. In some examples, a desired sustainability score may be entered into the pool automation controller 101 and the pool automation controller 101 may adjust the current supplied to pool equipment, after measuring the power consumption of the pool equipment, to align the sustainability score with the desired sustainability score.

In yet another example of an aggregate or derivative operation, the processing subsystem can be used to determine the power consumption of particular modes of operation of pieces of pool equipment. For example, a first piece of pool or spa equipment can be configured to operate in a first mode of operation. For instance, a heater 113 can be set at a first temperature setting. The process 200 described above, or a variation described herein, can be used to determine a power consumption at the first setting. Then, the piece of pool or spa equipment can be configured to operate in a second mode of operation, such as a heater 113 at a higher or lower temperature setpoint. The mode of operation can be changed using a control device 127 such as a relay or digital controller to remotely change the mode of operation and thereby control power to the equipment. The process 200 described above, or a variation described herein, can again be used to determine a power consumption based on one or more induced currents. The power consumption of the mode of operation can then be determined by the processing subsystem 123 based on a difference between the power consumption before and after changing the mode of operation. For instance, if the power consumption of the heater 113 is measured first at a high temperature and then at a low temperature, the difference in power consumption can be used to determine the power consumption at the high temperature and/or the low temperature.

Other examples of power consumption measurements for modes of operation for pieces of pool or spa equipment that can be measured include power consumption for circulation pump speed (e.g., RPMs), lighting system settings, filtration system modes, automated cleaning system status, and so on.

At block 208, the computing system outputs a command to a second control device to cause a second piece of pool or spa equipment to be connected to the AC electrical input. For example, the second control device may be a relay or digital controller that controls power to the second piece of pool or spa equipment using a switch or remotely operated digital control.

At block 210, the computing system receives information about one or more second induced currents from the one or more inductance coils. This measurement can proceed substantially as the measurement described above in block 202. In some examples, different pieces of pool or spa equipment may be connected to the AC electrical input using a different wiring scheme, in which case a different measurement procedure can be followed.

At block 212, the computing system determines a second power consumption by the second piece of connected piece of pool or spa equipment based on the one or more second induced currents. The second power consumption can be based on a difference between the first and second induced currents.

At block 214, the computing system outputs the first and second power consumptions. For example, the first and second power consumptions can be displayed using an appropriate user interface (“UI”) such as an external display of the pool automation controller 101 or a suitable graphical user interface (“GUI”) accessible using the pool automation controller 101. In some examples, the first and second power consumptions can be output to a remote server and displayed on a GUI such as a web page accessible over the internet 121.

In some examples, responsive to the power consumption(s) exceeding a predetermined threshold for a given piece of equipment, the respective control device can be effectuated to control power to the piece of pool or spa equipment to cause it to be disconnected from the electrical input. For instance, a region or jurisdiction may have regulatory requirements or maxima for power consumption. In another example, a region or jurisdiction may have rewards (e.g., discounts or tax benefits) for minimizing power consumption for pool and spa equipment. The processing subsystem 123 can measure power consumption and deactivate equipment consuming too much power using a control device 127. Similarly, the aggregate measurements described above can be similarly used to prevent exceeding other aggregate predetermined thresholds.

The operations described above for blocks 202-214 can be repeated as needed for other pieces of equipment. For example, to measure the power consumption for a third piece of equipment, the computing system can output commands to the control devices 127 to cause the first or second pieces of pool or spa equipment to be disconnected or otherwise unpowered from the AC electrical input. Then the computing system can output additional commands to the control devices 127 to cause a third piece of pool or spa equipment to be connected or otherwise powered to the AC electrical input and/or to cause all other pieces of pool or spa equipment to be disconnected or otherwise unpowered from the AC electrical input. The power consumption of the third piece of pool or spa equipment based on one or more third induced currents can then be measured using, for example, a measured difference in the induced current.

FIG. 3 shows a flow chart depicting an example process 300 for iteratively testing the power consumption of equipment in a pool or spa system, according to some examples of the present disclosure. This process, and any other processes described herein, is illustrated as a logical flow diagram, each operation of which represents a sequence of operations that can be implemented in hardware, computer instructions, or a combination thereof. In the context of computer instructions, the operations may represent computer-executable instructions stored on one or more non-transitory computer-readable storage media that, when executed by one more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the process.

Additionally, some, any, or all of the processes described herein may be performed under the control of one or more computer systems configured with specific executable instructions and may be implemented as code (e.g., executable instructions, one or more computer programs, or one or more applications) executing collectively on one or more processors, by hardware, or combinations thereof. As noted above, the code may be stored on a non-transitory computer-readable storage medium, for example, in the form of a computer program including a plurality of instructions executable by one or more processors.

The process 300 begins at block 302 by the pool automation controller 101 selecting a first equipment for a power consumption measurement. For example, the processing subsystem 123 of pool automation controller 101 may select the circulation pump 117 as the first equipment for the power consumption measurement

At block 304, the processing subsystem 123 of pool automation controller 101 switches on power to the first equipment. For example, the processing subsystem 123 can output commands to the control devices 127 to control power to the first piece of equipment by causing a removeable coupling such as a relay, mechanical actuator, or local digital controller to connect the piece of equipment with the AC electrical input. In some examples, this may include more granular operation of modes of the equipment and/or adjustment of various elements in the system that might impact power consumption of the first equipment. For example, the first equipment may be operated in a first mode, then a second mode, etc., while also making other adjustments to system elements (e.g., adjusting valves) and/or registering current states of system elements (e.g., pressures, valve states for non-automated valves, temperature levels, etc.). The first phase 103 of current (measured by the first coil 109 of the pool automation controller 101) and the second phase 105 of current (measured by the second coil 111 of the pool automation controller 101) may be exclusively dependent on the energy demands of the circulation pump 117 at the measured time.

At block 306, a processing subsystem 123 of the pool automation controller 101 may measure the current flowing through the first coil 109 and the second coil 111 for a fixed time interval. The fixed time interval may be determined by the processing subsystem 123 of the pool automation controller 101. Probes, leads, or other suitable instruments in communication with the processing subsystem 123 of the pool automation controller may be placed on both sides of the first coil 109 and both sides of the second coil 111 to measure current passing through the coils. By doing so, the processing subsystem 123 can determine the power consumption of the first piece of pool or spa equipment based on the measured induced currents.

In some examples, the power consumption of the first piece of pool or spa equipment can be determined using a difference between the measured current before and after the first piece of pool or spa equipment was turned on in block 304. For instance, the processing subsystem 123 can measure and temporarily record an induced current prior to the first piece of pool or spa equipment being turned on and then again afterwards. The arithmetic difference between the two induced currents may be proportional or otherwise related to the determined power consumption. For example, the difference can be related to power consumption through direct proportionality, nonlinear functions, phase angle differences, voltage drops, and so on.

At block 308, the processing subsystem 123 of the pool automation controller 101 may record the power consumption of the component. In the present example, the processing subsystem 123 of the pool automation controller 101 may record the power consumption of the circulation pump 117. The processing subsystem 123 may record the power consumption after calculating power consumption based on the current readings from the first coil 109 and the second coil 111.

At block 310, the processing subsystem 123 of the pool automation controller 101 may check for unrecorded equipment. If an equipment is present that has not been recorded, the process 300 may advance to block 312, in which the pool automation controller 101 will select the next component and repeat the steps of blocks 302-308 for that next component. For example, the processing subsystem 123 of the pool automation controller 101 may conclude the power consumption of the heater 113 has not been recorded and may select the heater 113 as the next component. If the power consumption of all equipment of a pool or spa system have been recorded, the process 300 may advance to block 314 and the process 300 may end.

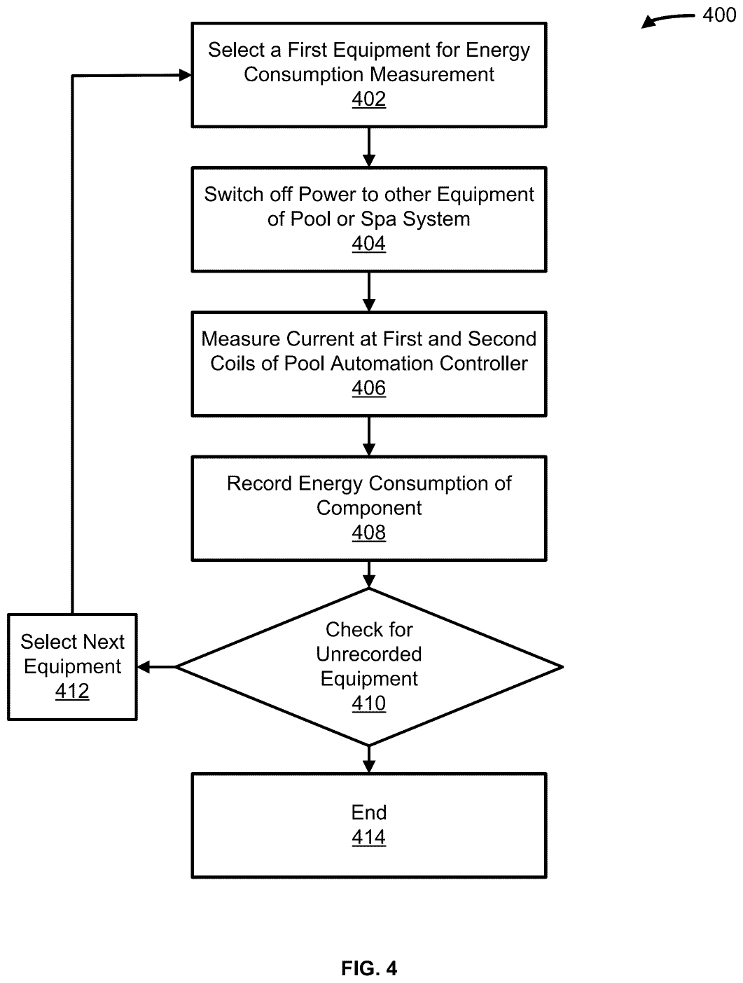

FIG. 4 shows another flow chart depicting an example process 400 for iteratively testing the power consumption of equipment in a pool or spa system, according to some examples of the present disclosure. This process, and any other processes described herein, is illustrated as a logical flow diagram, each operation of which represents a sequence of operations that can be implemented in hardware, computer instructions, or a combination thereof. In the context of computer instructions, the operations may represent computer-executable instructions stored on one or more non-transitory computer-readable storage media that, when executed by one more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the process.

Additionally, some, any, or all of the processes described herein may be performed under the control of one or more computer systems configured with specific executable instructions and may be implemented as code (e.g., executable instructions, one or more computer programs, or one or more applications) executing collectively on one or more processors, by hardware, or combinations thereof. As noted above, the code may be stored on a non-transitory computer-readable storage medium, for example, in the form of a computer program including a plurality of instructions executable by one or more processors.

The process 400 begins at block 402 by the pool automation controller 101 selecting a first equipment for a power consumption measurement. For example, the processing subsystem 123 of pool automation controller 101 may select the circulation pump 117 as the first equipment for the power consumption measurement. The first equipment may be powered on. In some examples, this may include more granular operation of modes of the equipment and/or adjustment of various elements in the system that might impact power consumption of the first equipment. For example, the first equipment may be operated in a first mode, then a second mode, etc., while also making other adjustments to system elements (e.g., adjusting valves) and/or registering current states of system elements (e.g., pressures, valve states for non-automated valves, temperature levels, etc.).

At block 404, the processing subsystem 123 of pool automation controller 101 operates control devices 127 to depower all other equipment of the pool or spa system. For example, the processing subsystem 123 can output commands to the control devices 127 to cause all pieces of pool or spa equipment other than the first piece of pool or spa equipment to be disconnected or otherwise unpowered from the electrical input. In the present example, the pool automation controller 101 may switch off the heater 113, the light 115, and other equipment 119, while leaving the circulation pump 117 powered on. Some equipment may be operated using a digital controller using an RS-485 serial interface. As a result, the first phase 103 of current (measured by the first coil 109 of the pool automation controller 101) and the second phase 105 of current (measured by the second coil 111 of the pool automation controller 101) may be exclusively dependent on the energy demands of the circulation pump 117 at the measured time.

At block 406, a processing subsystem 123 of the pool automation controller 101 may measure the current flowing through the first coil 109 and the second coil 111 for a fixed time interval. The fixed time interval may be determined by the processing subsystem 123 of the pool automation controller 101. Probes, leads, or other suitable instruments in communication with the processing subsystem 123 of the pool automation controller may be placed on both sides of the first coil 109 and both sides of the second coil 111 to measure current passing through the coils. By doing so, the processing subsystem 123 can determine the power consumption of the first piece of pool or spa equipment based on the measured induced currents.

At block 408, the processing subsystem 123 of the pool automation controller 101 may record the power consumption of the component. In the present example, the processing subsystem 123 of the pool automation controller 101 may record the power consumption of the circulation pump 117. The processing subsystem 123 may record the power consumption after calculating power consumption based on the current readings from the first coil 109 and the second coil 111.

At block 410, the processing subsystem 123 of the pool automation controller 101 may check for unrecorded equipment. If an equipment is present that has not been recorded, the process 400 may advance to block 412, in which the pool automation controller 101 will select the next component and repeat the steps of blocks 402-408 for that next component. For example, the processing subsystem 123 of the pool automation controller 101 may conclude the power consumption of the heater 113 has not been recorded and may select the heater 113 as the next component. If the power consumption of all equipment of a pool or spa system have been recorded, the process 400 may advance to block 314 and the process 400 may end.

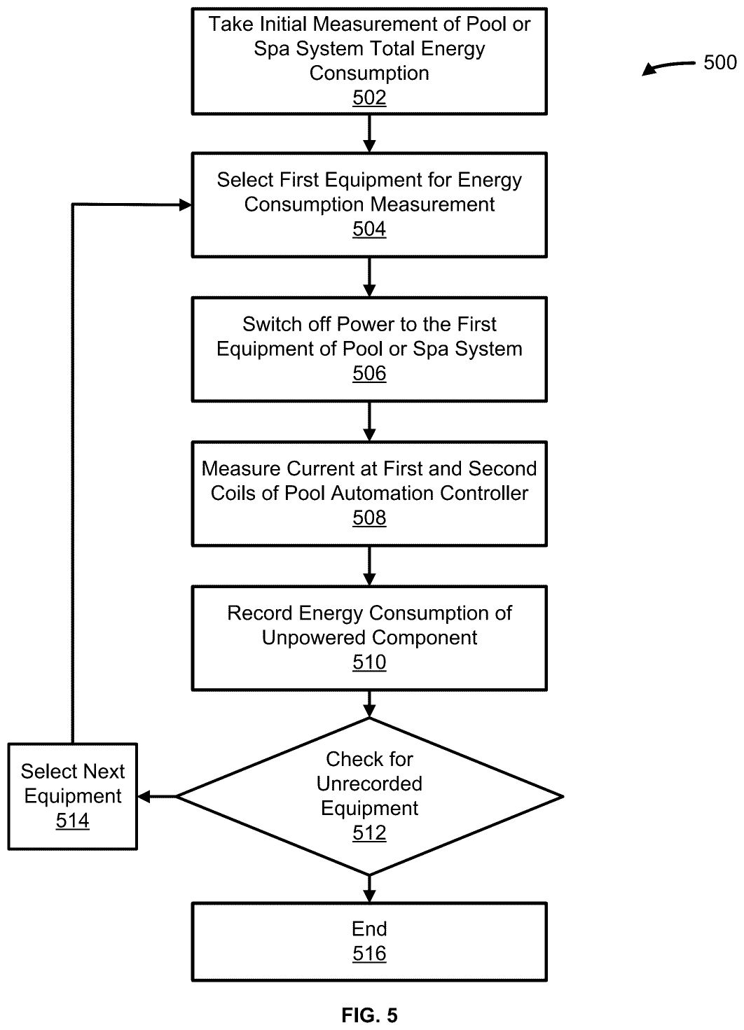

FIG. 5 shows a flow chart depicting an example process 500 for iteratively deducing the power consumption of equipment in a pool or spa system, according to some examples of the present disclosure. This process, and any other processes described herein, is illustrated as a logical flow diagram, each operation of which represents a sequence of operations that can be implemented in hardware, computer instructions, or a combination thereof. In the context of computer instructions, the operations may represent computer-executable instructions stored on one or more non-transitory computer-readable storage media that, when executed by one more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the process.

Additionally, some, any, or all of the processes described herein may be performed under the control of one or more computer systems configured with specific executable instructions and may be implemented as code (e.g., executable instructions, one or more computer programs, or one or more applications) executing collectively on one or more processors, by hardware, or combinations thereof. As noted above, the code may be stored on a non-transitory computer-readable storage medium, for example, in the form of a computer program including a plurality of instructions executable by one or more processors.

The process 500 differs from the process 400 depicted in FIG. 4 because rather than directly measuring the power consumption of a pool or spa equipment by measuring current flowing to the pool or spa component, the process 500 deduces the power consumption of the pool or spa equipment by using a recorded reduction in current as compared to an initial measurement of total power consumption.

The process 500 begins at block 502 by the processing subsystem 123 of pool automation controller 101 taking an initial measurement of current flow when every piece of equipment of a pool or spa system is powered on. For example, all control devices 127 can be effectuated to cause all pieces of pool or spa equipment to be connected to the electrical input 102. This initial measurement will be used to later deduce the consumption of individual pool or spa equipment. In the present example, the initial measurement may reflect current running through a circulation pump 117, a light 115, a heater 113, and other equipment 119. The processing subsystem 123 of the pool automation controller 101 may calculate the power consumption of the entire pool or spa system based on the initial current reading.

At block 504, the pool automation controller 101 selects a first equipment for power consumption measurement. As in the previous example, the pool automation controller 101 may select the circulation pump 117 as the first equipment for measurement.

At block 506, the pool automation controller 101 switches off the component selected as the first equipment. For example, the processing subsystem 123 can output commands to the control devices 127 to cause the first equipment to be powered off from the electrical input. In the present example, the pool automation controller 101 switches off the circulation pump 117. The remaining equipment, such as the heater 113, the light 115, and other equipment 119, may remain powered on. As a result, the first phase 103 of current (measured by the first coil 109 of the pool automation controller 101) and the second phase 104 of current (measured by the second coil 111 of the pool automation controller 101) may fall in proportion to the power consumption of the circulation pump 117.

At block 508, the processing subsystem 123 of the pool automation controller 101 may measure the current flowing through the first coil 109 and the second coil 111 for a fixed time interval to determine a power consumption of the first equipment based on one or more measured induced currents. The fixed time interval may be determined by the processing subsystem 123 of the pool automation controller 101. Probes, leads, or other suitable instruments in communication with the processing subsystem 123 of the pool automation controller may be placed on both sides of the first coil 109 and both sides of the second coil 111 to measure current passing through the coils.

At block 510, the processing subsystem 123 of the pool automation controller 101 may record the power consumption of the unpowered equipment by subtracting a measured power consumption of the powered equipment from the initial measurement of the pool or spa system's total power consumption. In the present example, the processing subsystem 123 would deduce the power consumption of the circulation pump 117 by subtracting the power consumption of the heater 113, the light 115, and other equipment 119 from the initial measurement taken in block 502 of the entire pool system 100.

At block 512, the processing subsystem 123 of the pool automation controller 101 may check for unrecorded equipment. If an equipment remains that has not been recorded, the process 500 may advance to block 514, in which the pool automation controller 101 will select the next equipment to be powered down. The pool automation controller 101 may also power on the previously powered off equipment to facilitate the aforementioned deductive process. In the present example, the processing subsystem 123 of the pool automation controller 101 may conclude the power consumption of the heater 113 has not been recorded and may select the heater 113 as the next component. The pool automation controller 101 may also power on the previously powered off circulation pump 117 to facilitate an isolated deduction of the heater's 113 power consumption. If the power consumption of all equipment of a pool or spa system has been recorded, the process 500 may advance to block 516 and the process 500 may end.

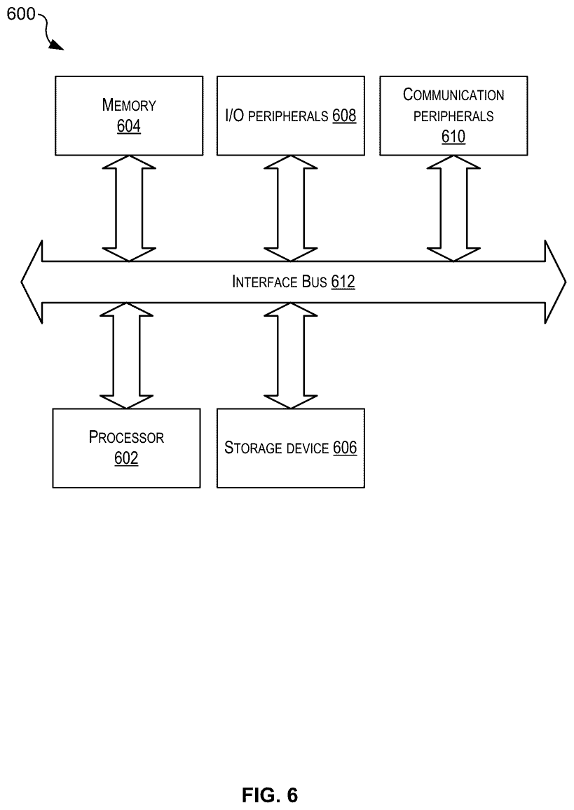

FIG. 6 illustrates examples of a computer system 600 that can be used for power consumption measurement of pool or spa equipment using a pool automation controller, according to some examples of the present disclosure. The computer system 600 may be a single computer such as a user computing device and/or can represent a distributed computing system such as one or more server computing devices. The computer system 600 is an example of the external computing devices, processing subsystem 123, controllers and/or microcontrollers of pool equipment and/or the pool automation controller 101, and the like.

The computer system 600 may include at least a processor 602, a memory 604, a storage device 606, input/output peripherals (I/O) 608, communication peripherals 610, and an interface bus 612. The interface bus 612 is configured to communicate, transmit, and transfer data, controls, and commands among the various components of the computer system 600. The memory 606 and the storage device 606 include computer-readable storage media, such as Random Access Memory (RAM), Read ROM, electrically erasable programmable read-only memory (EEPROM), hard drives, CD-ROMs, optical storage devices, magnetic storage devices, electronic non-volatile computer storage, for example Flash® memory, and other tangible storage media. Any of such computer-readable storage media can be configured to store instructions or program code embodying aspects of the disclosure. The memory 604 and the storage device 606 also include computer-readable signal media. A computer-readable signal medium includes a propagated data signal with computer-readable program code embodied therein. Such a propagated signal can take any of a variety of forms including, but not limited to, electromagnetic, optical, or any combination thereof. A computer-readable signal medium includes any computer-readable medium that is not a computer-readable storage medium and that can communicate, propagate, or transport a program for use in connection with the computer system 600.

Further, the memory 604 may include an operating system, programs, and applications. The processor 602 is configured to execute the stored instructions and includes, for example, a logical processing unit, a microprocessor, a digital signal processor, and other processors. The memory 604 and/or the processor 602 can be virtualized and can be hosted within another computing system of, for example, a cloud network or a data center. The I/O peripherals 608 may include user interfaces, such as a keyboard, screen (e.g., a touch screen), microphone, speaker, other input/output devices, and computing components, such as graphical processing units, serial ports, parallel ports, universal serial buses, and other input/output peripherals. The I/O peripherals 608 are connected to the processor 602 through any of the ports coupled to the interface bus 612. The communication peripherals 610 are configured to facilitate communication between the computer system 600 and other computing devices over a communications network and include, for example, a network inference controller, modem, wireless and wired interface cards, antenna, and other communication peripherals.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude inclusion of such modifications, variations, and/or additions to the present subject matter as would be readily apparent to one of ordinary skill in the art. Indeed, the methods and systems described herein may be embodied in a variety of other forms; furthermore, various omissions, substitutions, and changes in the form of the methods and systems described herein may be made without departing from the spirit of the present disclosure. The accompanying claims and their equivalents are intended to cover such forms or modifications as would fall within the scope and spirit of the present disclosure.

Although applicant has described devices and techniques for use principally with swimming pools and spas, persons skilled in the relevant field will recognize that the present invention may be employed in connection with other objects and in other manners. Finally, references to “pools” and “swimming pools” herein may also refer to spas or other water containing vessels used for recreation or therapy and for which cleaning is needed or desired.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical, electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multipurpose microprocessor-based computing systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain examples require at least one of X, at least one of Y, or at least one of Z to each be present.

Use herein of the word “or” is intended to cover inclusive and exclusive OR conditions. In other words, A or B or C includes any or all of the following alternative combinations as appropriate for a particular usage: A alone; B alone; C alone; A and B only; A and C only; B and C only; and all three of A and B and C.

The use of the terms “a” and “an” and “the” and similar referents in the context of describing the disclosed examples (especially in the context of the following claims) are to be construed to cover both the singular and the plural, unless otherwise indicated herein or clearly contradicted by context. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. The use of “adapted to” or “configured to” herein is meant as open and inclusive language that does not foreclose devices adapted to or configured to perform additional tasks or steps. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. Additionally, the use of “based on” is meant to be open and inclusive, in that a process, step, calculation, or other action “based on” one or more recited conditions or values may, in practice, be based on additional conditions or values beyond those recited. Similarly, the use of “based at least in part on” is meant to be open and inclusive, in that a process, step, calculation, or other action “based at least in part on” one or more recited conditions or values may, in practice, be based on additional conditions or values beyond those recited. Headings, lists, and numbering included herein are for ease of explanation only and are not meant to be limiting.

The various features and processes described above may be used independently of one another or may be combined in various ways. All possible combinations and sub-combinations are intended to fall within the scope of the present disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed examples. Similarly, the example systems and components described herein may be configured differently than described. For example, elements may be added to, removed from, or rearranged compared to the disclosed examples.

All references, including publications, patent applications, and patents, cited herein are hereby incorporated by reference to the same extent as if each reference were individually and specifically indicated to be incorporated by reference and were set forth in its entirety herein.

### Examples

As used below, any reference to a series of examples is to be understood as a reference to each of those examples disjunctively (e.g., “Examples 1-4” is to be understood as “Examples 1, 2, 3, or 4”).

Example 1 is a pool automation controller for measuring power consumption of pool or spa equipment associated with a pool or spa, comprising: one or more inductance coils configured to measure a current induced by an alternating-current (“AC”) electrical input; one or more control devices configured to control power directed to one or more pieces of pool or spa equipment electrically connected to the AC electrical input; one or more non-transitory computer-readable media; and one or more processors communicatively coupled to the one or more non-transitory computer-readable media, the one or more processors configured to execute processor-executable instructions stored in the non-transitory computer-readable media to perform operations including: identifying a first piece of pool or spa equipment based on a status of a first control device; receiving information about one or more first induced currents from the one or more inductance coils; determining a first power consumption by the first piece of pool or spa equipment based on the one or more first induced currents; and outputting the first power consumption.

Example 2 is the pool automation controller of example(s) 1, wherein the one or more control devices include an electromechanical relay for operating a remote switch.

Example 3 is the pool automation controller of example(s) 1, wherein the one or more control devices include a digital controller for operating a remote switch.

Example 4 is the pool automation controller of example(s) 1, wherein: the AC electrical input is a split-phase AC electrical input comprising two hot wires and a neutral wire; and each of the two hot wires has a corresponding inductance coil.

Example 5 is the pool automation controller of example(s) 4, further comprising a processing subsystem, the processing subsystem comprising: an amplifier for each of the one or more inductance coils; and a digitizer, wherein the information about the one or more first induced currents comprises a measurement of the current in each phase of the split-phase AC electrical input.

Example 6 is the pool automation controller of example(s) 1, wherein: the AC electrical input is a single-phase AC electrical input comprising a hot wire and a neutral wire; and the hot wire has a corresponding inductance coil.

Example 7 is the pool automation controller of example(s) 1, wherein: a plurality of pieces of pool or spa equipment are electrically connected to the AC electrical input, and determining the first power consumption by the first piece of pool or spa equipment based on the one or more first induced current comprises: outputting a first command to the one or more control devices to cause all of the plurality of pieces of pool or spa equipment other than the first piece of pool or spa equipment to be unpowered by the electrical input; measuring the one or more first induced currents; and computing the first power consumption of the first piece of pool or spa equipment using the one or more first induced currents.

Example 8 is the pool automation controller of example(s) 7, the operations further comprising: outputting a second command to the one or more control devices to cause the first piece of pool or spa equipment to be unpowered by the electrical input; outputting a third command to the one or more control devices to cause a second piece of pool or spa equipment to be powered by the electrical input; outputting a fourth command to the one or more control devices to cause all other pieces of pool or spa equipment other than the second piece of pool or spa equipment to be unpowered by the electrical input; and determining a second power consumption of the second piece of pool or spa equipment based on one or more second induced currents.

Example 9 is the pool automation controller of example(s) 1, wherein: a plurality of pieces of pool or spa equipment are electrically connected to the AC electrical input, and determining the first power consumption by the first piece of pool or spa equipment based on the one or more first induced current comprises: outputting a first command to the one or more control devices to cause all of the plurality of pieces of pool or spa equipment to be powered by the AC electrical input; measuring one or more second induced currents; outputting a second command to the one or more control devices to cause the first piece of pool or spa equipment to be unpowered by the AC electrical input; measuring the one or more first induced currents; and computing the first power consumption of the first piece of pool or spa equipment using a difference between the one or more second induced currents and the one or more first induced currents.

Example 10 is the pool automation controller of example(s) 1, the operations further comprising: configuring the first piece of pool or spa equipment to operate in a first mode of operation; determining a second power consumption based on one or more second induced currents while the first piece of pool or spa equipment is operating in the first mode of operation; configuring the first piece of pool or spa equipment to operate in a second mode of operation; determining a third power consumption based on one or more third induced currents while the first piece of pool or spa equipment is operating in the second mode of operation; and determining a power consumption profile of the first mode of operation based on a difference between the second power consumption and the third power consumption.

Example 11 is the pool automation controller of example(s) 1, wherein the first piece of pool or spa equipment is a heater, a light, a cleaner, or a circulation pump.

Example 12 is the pool automation controller of example(s) 1, wherein a plurality of pieces of pool or spa equipment are electrically connected to the AC electrical input, and the operations further comprise: determining a power consumption measurement plan comprising instructions, each instruction including at least one command to the one or more control devices to power or remove power from a particular piece of pool or spa equipment of the plurality of pieces of pool or spa equipment from the AC electrical input to enable a power consumption measurement; and executing the power consumption measurement plan to cause a power consumption measurement for each of the plurality of pieces of pool or spa equipment.

Example 13 is the pool automation controller of example(s) 12, the operations further comprising combining the power consumption measurement for each of the plurality of pieces of pool or spa equipment to compute an aggregate power consumption measurement.

Example 14 is the pool automation controller of example(s) 1, the operations further comprising, responsive to the first power consumption exceeding a predetermined threshold, outputting a command to the one or more control devices to cause the first piece of pool or spa equipment to be unpowered by the AC electrical input.

Example 15 is a method, comprising: receiving information about one or more first induced currents from one or more inductance coils configured to measure a current induced by an AC electrical input; identifying a first connected piece of pool or spa equipment based on a status of a first control device configured to control power to an electrically connected piece of pool or spa equipment of a plurality of pieces of pool or spa equipment from the AC electrical input; determining a first power consumption by the first connected piece of pool or spa equipment based on the one or more first induced currents; and outputting the first power consumption.

Example 16 is the method of example(s) 15, wherein: determining the first power consumption by the first connected piece of pool or spa equipment based on the one or more first induced current comprises: outputting a first command to one or more control devices, including the first control device, to cause all pieces of pool or spa equipment other than the first connected piece of pool or spa equipment to be unpowered by the AC electrical input; and measuring the one or more first induced currents, the method further comprising: outputting a second command to the one or more control devices to cause the first connected piece of pool or spa equipment to be unpowered by the AC electrical input; outputting a third command to the one or more control devices to cause a second connected piece of pool or spa equipment to be powered by the AC electrical input; and determining a second power consumption of the second connected piece of pool or spa equipment based on one or more second induced currents.

Example 17 is the method of example(s) 15, wherein determining the first power consumption by the first connected piece of pool or spa equipment based on the one or more first induced current comprises: outputting a first command to one or more control devices, including the first control device, to cause all of the plurality of pieces of pool or spa equipment to be powered by the AC electrical input; measuring one or more second induced currents; outputting a second command to the one or more control devices to cause the first connected piece of pool or spa equipment to be unpowered by the AC electrical input; measuring the one or more first induced currents; and computing the first power consumption of the first connected piece of pool or spa equipment using a difference between the one or more second induced currents and the one or more first induced currents.

Example 18 is the method of example(s) 15, further comprising: configuring the first connected piece of pool or spa equipment to operate in a first mode of operation; determining a second power consumption based on one or more second induced currents while the first connected piece of pool or spa equipment is operating in the first mode of operation; configuring the first connected piece of pool or spa equipment to operate in a second mode of operation; determining a third power consumption based on one or more third induced currents while the first connected piece of pool or spa equipment is operating in the second mode of operation; and determining a power consumption profile of the first mode of operation based on a difference between the second power consumption and the third power consumption.

Example 19 is the method of example(s) 15, further comprising: determining a power consumption measurement plan comprising instructions, each instruction including at least one command to one or more control devices, including the first control device, to power or remove power from a particular piece of pool or spa equipment of the plurality of pieces of pool or spa equipment from the AC electrical input to enable a power consumption measurement; executing the power consumption measurement plan to cause a power consumption measurement for each of the plurality of pieces of pool or spa equipment; and combining the power consumption measurement for each of the plurality of pieces of pool or spa equipment to compute an aggregate power consumption measurement.

Example 20 us a non-transitory computer-readable medium storing processor-executable instructions configured to cause one or more processors to: receive information about one or more induced currents from one or more inductance coils configured to measure a current induced by an AC electrical input; identify a first connected piece of pool or spa equipment based on a status of a first control device configured to control power to an electrically connected piece of pool or spa equipment of a plurality of pieces of pool or spa equipment from the AC electrical input; determine a power consumption by the first connected piece of pool or spa equipment based on one or more first induced currents; and output the power consumption.

What is claimed is:

1. A pool automation controller for measuring power consumption of pool or spa equipment associated with a pool or spa, comprising:
one or more inductance coils configured to measure a current induced by an alternating-current (“AC”) electrical input;
one or more control devices configured to control power directed to one or more pieces of pool or spa equipment electrically connected to the AC electrical input;
one or more non-transitory computer-readable media; and
one or more processors communicatively coupled to the one or more non-transitory computer-readable media, the one or more processors configured to execute processor-executable instructions stored in the non-transitory computer-readable media to perform operations including:
identifying a first piece of pool or spa equipment based on a status of a first control device;
receiving information about one or more first induced currents from the one or more inductance coils;
determining a first power consumption by the first piece of pool or spa equipment based on the one or more first induced currents; and
outputting the first power consumption.

2. The pool automation controller of claim 1, wherein the one or more control devices include an electromechanical relay for operating a remote switch.

3. The pool automation controller of claim 1, wherein the one or more control devices include a digital controller for operating a remote switch.

4. The pool automation controller of claim 1, wherein:
the AC electrical input is a split-phase AC electrical input comprising two hot wires and a neutral wire; and
each of the two hot wires has a corresponding inductance coil.

5. The pool automation controller of claim 4, further comprising a processing subsystem, the processing subsystem comprising:
an amplifier for each of the one or more inductance coils; and
a digitizer,
wherein the information about the one or more first induced currents comprises a measurement of the current in each phase of the split-phase AC electrical input.

6. The pool automation controller of claim 1, wherein:
the AC electrical input is a single-phase AC electrical input comprising a hot wire and a neutral wire; and
the hot wire has a corresponding inductance coil.

7. The pool automation controller of claim 1, wherein:
a plurality of pieces of pool or spa equipment are electrically connected to the AC electrical input, and
determining the first power consumption by the first piece of pool or spa equipment based on the one or more first induced current comprises:
outputting a first command to the one or more control devices to cause all of the plurality of pieces of pool or spa equipment other than the first piece of pool or spa equipment to be unpowered by the electrical input;
measuring the one or more first induced currents; and
computing the first power consumption of the first piece of pool or spa equipment using the one or more first induced currents.

8. The pool automation controller of claim 7, the operations further comprising:
outputting a second command to the one or more control devices to cause the first piece of pool or spa equipment to be unpowered by the electrical input;
outputting a third command to the one or more control devices to cause a second piece of pool or spa equipment to be powered by the electrical input;
outputting a fourth command to the one or more control devices to cause all other pieces of pool or spa equipment other than the second piece of pool or spa equipment to be unpowered by the electrical input; and
determining a second power consumption of the second piece of pool or spa equipment based on one or more second induced currents.

9. The pool automation controller of claim 1, wherein:
a plurality of pieces of pool or spa equipment are electrically connected to the AC electrical input, and
determining the first power consumption by the first piece of pool or spa equipment based on the one or more first induced current comprises:
outputting a first command to the one or more control devices to cause all of the plurality of pieces of pool or spa equipment to be powered by the AC electrical input;
measuring one or more second induced currents;
outputting a second command to the one or more control devices to cause the first piece of pool or spa equipment to be unpowered by the AC electrical input;
measuring the one or more first induced currents; and
computing the first power consumption of the first piece of pool or spa equipment using a difference between the one or more second induced currents and the one or more first induced currents.

10. The pool automation controller of claim 1, the operations further comprising:
configuring the first piece of pool or spa equipment to operate in a first mode of operation;
determining a second power consumption based on one or more second induced currents while the first piece of pool or spa equipment is operating in the first mode of operation;
configuring the first piece of pool or spa equipment to operate in a second mode of operation;
determining a third power consumption based on one or more third induced currents while the first piece of pool or spa equipment is operating in the second mode of operation; and
determining a power consumption profile of the first mode of operation based on a difference between the second power consumption and the third power consumption.

11. The pool automation controller of claim 1, wherein the first piece of pool or spa equipment is a heater, a light, a cleaner, or a circulation pump.

12. The pool automation controller of claim 1, wherein a plurality of pieces of pool or spa equipment are electrically connected to the AC electrical input, and the operations further comprise:
determining a power consumption measurement plan comprising instructions, each instruction including at least one command to the one or more control devices to power or remove power from a particular piece of pool or spa equipment of the plurality of pieces of pool or spa equipment from the AC electrical input to enable a power consumption measurement; and
executing the power consumption measurement plan to cause a power consumption measurement for each of the plurality of pieces of pool or spa equipment.

13. The pool automation controller of claim 12, the operations further comprising combining the power consumption measurement for each of the plurality of pieces of pool or spa equipment to compute an aggregate power consumption measurement.

14. The pool automation controller of claim 1, the operations further comprising, responsive to the first power consumption exceeding a predetermined threshold, outputting a command to the one or more control devices to cause the first piece of pool or spa equipment to be unpowered by the AC electrical input.

15. A method, comprising:
receiving information about one or more first induced currents from one or more inductance coils configured to measure a current induced by an AC electrical input;
identifying a first connected piece of pool or spa equipment based on a status of a first control device configured to control power to an electrically connected piece of pool or spa equipment of a plurality of pieces of pool or spa equipment from the AC electrical input;
determining a first power consumption by the first connected piece of pool or spa equipment based on the one or more first induced currents; and
outputting the first power consumption.

16. The method of claim 15, wherein:
determining the first power consumption by the first connected piece of pool or spa equipment based on the one or more first induced current comprises:
outputting a first command to one or more control devices, including the first control device, to cause all pieces of pool or spa equipment other than the first connected piece of pool or spa equipment to be unpowered by the AC electrical input; and
measuring the one or more first induced currents,
the method further comprising:
outputting a second command to the one or more control devices to cause the first connected piece of pool or spa equipment to be unpowered by the AC electrical input;
outputting a third command to the one or more control devices to cause a second connected piece of pool or spa equipment to be powered by the AC electrical input; and
determining a second power consumption of the second connected piece of pool or spa equipment based on one or more second induced currents.

17. The method of claim 15, wherein determining the first power consumption by the first connected piece of pool or spa equipment based on the one or more first induced current comprises:
outputting a first command to one or more control devices, including the first control device, to cause all of the plurality of pieces of pool or spa equipment to be powered by the AC electrical input;
measuring one or more second induced currents;
outputting a second command to the one or more control devices to cause the first connected piece of pool or spa equipment to be unpowered by the AC electrical input;
measuring the one or more first induced currents; and
computing the first power consumption of the first connected piece of pool or spa equipment using a difference between the one or more second induced currents and the one or more first induced currents.

18. The method of claim 15, further comprising:
configuring the first connected piece of pool or spa equipment to operate in a first mode of operation;
determining a second power consumption based on one or more second induced currents while the first connected piece of pool or spa equipment is operating in the first mode of operation;
configuring the first connected piece of pool or spa equipment to operate in a second mode of operation;
determining a third power consumption based on one or more third induced currents while the first connected piece of pool or spa equipment is operating in the second mode of operation; and
determining a power consumption profile of the first mode of operation based on a difference between the second power consumption and the third power consumption.

19. The method of claim 15, further comprising:
determining a power consumption measurement plan comprising instructions, each instruction including at least one command to one or more control devices, including the first control device, to power or remove power from a particular piece of pool or spa equipment of the plurality of pieces of pool or spa equipment from the AC electrical input to enable a power consumption measurement;
executing the power consumption measurement plan to cause a power consumption measurement for each of the plurality of pieces of pool or spa equipment; and
combining the power consumption measurement for each of the plurality of pieces of pool or spa equipment to compute an aggregate power consumption measurement.

20. A non-transitory computer-readable medium storing processor-executable instructions configured to cause one or more processors to:
receive information about one or more induced currents from one or more inductance coils configured to measure a current induced by an AC electrical input;
identify a first connected piece of pool or spa equipment based on a status of a first control device configured to control power to an electrically connected piece of pool or spa equipment of a plurality of pieces of pool or spa equipment from the AC electrical input;
determine a power consumption by the first connected piece of pool or spa equipment based on one or more first induced currents; and
output the power consumption.
